(19) United States
(12) Patent Application Publication
(10) Pub. No.: US 2022/0089475 A1
(43) Pub. Date: Mar. 24, 2022

(54) CONDUCTIVE PASTE FOR SOLAR CELL ELECTRODE AND SOLAR CELL MANUFACTURED USING SAME

(71) Applicant: LS-NIKKO COPPER INC., Ulsan (KR)

(72) Inventors: Tae Hyun JUN, Seongnam (KR); In Chul KIM, Yongin (KR); Min Soo KO, Seoul (KR); Hwa Young NOH, Hwaseong (KR); Mun Seok JANG, Seoul (KR); Chung Ho KIM, Namyangju (KR); Kang Ju PARK, Seongnam (KR)

(21) Appl. No.: 17/298,418

(22) PCT Filed: Nov. 29, 2019
(86) PCT No.: PCT/KR2019/016805

§ 371 Date: May 28, 2021

(30) Foreign Application Priority Data
Nov. 30, 2018 (KR) 10-2018-0153122

(51) Int. Cl. C03C 4/14; C03C 8/18; C03C 8/16; H01L 31/0224

(52) U.S. Cl. CPC C03C 4/14; H01L 31/022425; C03C 8/16; C03C 8/18

(57) ABSTRACT

Proposed is a conductive paste for a solar cell electrode. The conductive paste includes a metal powder, a glass frit, an organic vehicle, a silicone oil and an additive. The use of the silicone oil included in the conductive paste resolves the problem of phase separation and significantly improves slip properties of the conductive paste, thereby enabling the implementation of fine line widths.

### TECHNICAL FIELD

The present disclosure relates to a conductive paste used for forming a solar cell electrode, and a solar cell manufactured using the same.

### BACKGROUND ART

A solar cell is a semiconductor device that converts solar energy into electrical energy, and generally has a p-n junction. The basic structure of the solar cell is the same as that of a diode. A solar cell device is generally constructed using a p-type silicon semiconductor substrate having a thickness of 160 to 250 μm. An n-type impurity layer having a thickness of 0.3 to 0.6 μm is formed on a light-receiving surface side of the silicon semiconductor substrate, and an anti-reflection film and a front electrode are formed thereon. Further, a back electrode is formed on a back surface of the p-type silicon semiconductor substrate.

The front electrode is formed in such a manner that a conductive paste formed by mixing silver-based conductive particles (silver powder), a glass frit, an organic vehicle, and additives is applied on the anti-reflection film, followed by firing. The back electrode is formed in such a manner that an aluminum paste composition composed of an aluminum powder, a glass frit, an organic vehicle, and additives is applied by screen printing or the like, followed by drying and then firing at a temperature of equal to or greater than 660° C. (melting point of aluminum). During firing, aluminum diffuses into the p-type silicon semiconductor substrate, thereby forming an Al—Si alloy layer between the back electrode and the p-type silicon semiconductor substrate, and at the same time, a p+layer is formed as an impurity layer by diffusion of aluminum atoms. The presence of such a p+layer prevents recombination of electrons and obtains a back surface field (BSF) effect that improves collection efficiency of generated carriers. A back silver electrode may be further positioned under the back aluminum electrode.

Meanwhile, the front electrode of the solar cell is mainly formed through a screen printing process. However, when slip properties of a paste are poor, there is a problem in that during screen printing, the paste cannot escape through a screen mesh, resulting that the electrode pattern may not be formed as designed but become uneven or nonuniform. Particularly, line breaks may occur or resistance may be greatly increased when a fine line width is realized. Therefore, slip properties of the paste are a very important factor.

### DISCLOSURE

### Technical Problem

The present disclosure employs the addition of a silicone oil to a paste in order to increase slip properties of the paste. However, in the case of the silicone oil, compatibility with an organic vehicle such as an organic solvent is poor and phase separation occurs, thus uniformity of the paste is impaired and storage stability is problematic, making it very difficult to use the silicone oil.

Accordingly, an objective of the present disclosure is to provide a paste composition for a solar cell electrode, the paste composition being capable of resolving the problem of phase separation occurring in the use of silicone oil while significantly improving slip properties, thereby realizing fine line widths, and to provide a high-efficiency solar cell in which the electrical characteristics of an electrode are improved due to an increased short-circuit current.

However, the objectives of the present disclosure are not limited to the above-mentioned objective, and other objectives not mentioned will be clearly understood by those skilled in the art from the following description.

### Technical Solution

In order to accomplish the above objective, the present disclosure provides a conductive paste for a solar cell electrode, the conductive paste including a metal powder, a glass frit, an organic vehicle, a silicone oil, and an additive, wherein the metal powder may be coated with a coating agent including an alkyl amine-based compound having an amine group in an alkyl chain having 8 to 20 carbon atoms or an alkyl carboxy-based compound having a carboxyl group in an alkyl chain having 8 to 20 carbon atoms.

Furthermore, the alkyl amine-based compound may include at least one selected from the group consisting of triethylamine, heptylamine, octadecylamine, hexadecylamine, decylamine, octylamine, didecylamine, and trioctylamine.

Furthermore, the alkyl carboxy-based compound may include at least one selected from the group consisting of capric acid, lauric acid, myristic acid, palmitic acid, stearic acid, arachidic acid, myristoleic acid, palmitoleic acid, oleic acid, and linoleic acid.

Furthermore, the silicone oil may be included in an amount of 0.1 to 2% by weight with respect to the total weight of the conductive paste.

Furthermore, the silicone oil may include at least one selected from the group consisting of phenyl trimethicone, dimethicone, cyclomethicone, polydimethylsiloxane, and silicone gum.

Furthermore, the additive may be included in an amount of 0.5 to 3% by weight with respect to the total weight of the conductive paste.

Furthermore, the additive may include at least one selected from the group consisting of octyldodecyl neopentanoate, tridecyl neopentanoate, dioctyl adipate, isotearyl neopentanoate, and iodopropynyl butylcarbamate.

The present disclosure further provides a solar cell including: a front electrode provided on a substrate; and a back electrode provided under the substrate, wherein the front electrode may be produced by applying the conductive paste, and then drying and firing the conductive paste.

### Advantageous Effects

According to a conductive paste according to the present disclosure, it is possible to provide a paste composition for a solar cell electrode, the paste composition being capable of resolving the problem of phase separation occurring in the use of a silicone oil while significantly improving slip properties, thereby enabling the implementation of fine line widths, and to provide a high-efficiency solar cell.

More specifically, the silicone oil is a raw material having the best slip properties and has an excellent effect on fine line width printing. When employing the use of the silicone oil in the conductive paste according to the present disclosure, it is possible to implement fine line widths by increasing slip properties.

Despite the fact that the silicone oil is difficult to use due to the problem of compatibility, the present disclosure can employ the introduction of an additive having compatibility with silicone oil to improve compatibility, which is the most problematic in the use of silicone oil, and improve long-term stability and liquid separation properties of the conductive paste through the improved compatibility. Thus, it is possible to provide a conductive paste with excellent printability and stability.

A solar cell including an electrode produced using the conductive paste can implement fine line widths, which can increase short-circuit current and decrease line resistance, thereby improving electrical characteristics. Thus, it is possible to provide a high-efficiency solar cell.

### DESCRIPTION OF DRAWINGS

FIGS. 1 and 2 illustrate images of solutions in which additives according to Example of the present disclosure and Comparative Example and silicone oils are mixed.

FIGS. 3 and 4 illustrate images of whether or not phase separation occurs after centrifugation of conductive pastes according Example of the present disclosure and Comparative Example.

FIGS. 5 and 6 illustrate graphs of measurement of elastic modulus and viscosity of the conductive pastes according to Example of the present disclosure and Comparative Example.

### BEST MODE

Prior to describing the present disclosure in detail below, it should be understood that the terms used herein are merely intended to describe specific embodiments and are not to be construed as limiting the scope of the present disclosure, which is defined by the appended claims. Unless otherwise defined, all terms including technical and scientific terms used herein have the same meaning as commonly understood by one of ordinary skill in the art to which this disclosure belongs.

Throughout this specification and the claims, unless otherwise defined, the terms “comprise”, “comprises”, and “comprising” will be understood to imply the inclusion of a stated object, a step or groups of objects, and steps, but not the exclusion of any other objects, steps or groups of objects or steps.

Meanwhile, unless otherwise noted, various embodiments of the present disclosure may be combined with any other embodiments. In particular, any feature which is mentioned preferably or favorably may be combined with any other features which may be mentioned preferably or favorably. Hereinafter, a description will be given of embodiments of the present disclosure and effects thereof with reference to the accompanying drawings.

A conductive paste composition for forming a solar cell electrode according to an embodiment of the present disclosure may include a conductive metal powder, a glass frit, an organic vehicle, a silicone oil, and an additive. The silicone oil is a material which has poor compatibility with water and poor compatibility with organic solvents, and thus is difficult to disperse uniformly. In particular, the silicone oil exhibits incompatibility with organic vehicles used in conductive pastes. However, for compatibility of the silicone oil, a conductive metal powder surface-coated with a coating agent is used, and an additive having compatibility with the silicone oil is used. This drastically improves the incompatibility problem of the silicone oil while greatly improving slip properties of the conductive paste and implementation of fine line widths.

Hereinafter, each component will be described in detail.

<Conductive Metal Powder>

As a conductive metal powder, a silver powder, copper powder, nickel powder, aluminum powder, or the like may be used. The silver powder is mainly used for a front electrode, and the aluminum powder is mainly used for a back electrode. Hereinafter, for convenience of description, the conductive metal powder will be described using the silver powder as an example. The following description can be equally applied to other metal powders.

The silver powder is preferably a pure silver powder. Alternatively, a silver-coated composite powder in which a silver layer is formed on at least a surface thereof, or an alloy including silver as a main component may be used. Further, other metal powders may be mixed and used. Examples may include aluminum, gold, palladium, copper, and nickel. The silver powder may have an average particle diameter of 0.1 to 10 μm, and preferably 0.5 to 5 μm when considering ease of pasting and density during firing, and the shape thereof may be at least one of spherical, acicular, plate-like, and amorphous. The silver powder may be used by mixing two or more powders having different average particle diameters, particle size distributions, and shapes. The amount of the silver powder is preferably 60 to 98% by weight with respect to the total weight of the paste composition for the electrode when considering electrode thickness formed during printing and linear resistance of the electrode.

The conductive metal powder is coated with a coating agent. The coating agent includes an alkyl amine-based compound having an amine group in an alkyl chain having 8 to 20 carbon atoms or an alkyl carboxy-based compound having a carboxyl group in an alkyl chain having 8 to 20 carbon atoms. Preferably, the coating agent includes a compound having an amine group or a carboxyl group in an alkyl chain having 15 to 20 carbon atoms. When the number of carbon atoms of the alkyl chain is less than 8, there is a problem in that a desired effect may not be exhibited. On the other hand, when the number of carbon atoms thereof exceeds 20, there is a problem in that solubility in a solvent may be low, and surface treatment may not be performed well. In addition, as the coating agent, either a coating agent with a saturated alkyl chain or a coating agent with an unsaturated alkyl chain may be used.

The compound having the amine group in the alkyl chain may include at least one selected from the group consisting of triethylamine, heptylamine, octadecylamine, hexadecylamine, decylamine, octylamine, didecylamine, and trioctylamine.

The compound having the carboxyl group in the alkyl chain may include: as a saturated fatty acid, at least one selected from the group consisting of capric acid, lauric acid, myristic acid, palmitic acid, stearic acid, and arachidic acid; and as an unsaturated fatty acid, at least one selected from the group consisting of myristoleic acid, palmitoleic acid, oleic acid, and linoleic acid.

Most preferably, a silver powder coated with octadecylamine is used, and the coating agent is preferably coated with a thickness of 0.1 to 50 nm on a surface of the metal powder. The coating may be performed in such a manner that a metal powder such as silver powder is added to an organic solvent in which the coating agent is dissolved, followed by stirring for a predetermined period of time, and filtering.

As a specific coating method, an alcohol solution including an alkyl amine-based compound or an alkyl carboxy-based compound may be added to a solution in which the conductive metal powder is dispersed, followed by stirring at 2000 to 5000 rpm for 10 to 30 minutes using a stirrer. As the alcohol solution including the alkyl amine-based compound or the alkyl carboxy-based compound, an alcohol solution in which 5 to 20 wt % of the compound is dissolved with respect to the total weight of the solution may be used. As an alcohol, methanol, ethanol, n-propanol, benzyl alcohol, terpineol, or the like may be used, and preferred is ethanol.

The coating agent may be used in an amount of 0.1 to 1.0 parts by weight with respect to 100 parts by weight of the conductive metal powder. When the amount thereof is less than 0.1 parts by weight, a small amount of the coating agent may be adsorbed on the surface of the conductive metal powder, resulting in aggregation occurring between powder particles, and the effect of improving compatibility of the silicone oil may be negligible. On the other hand, when the amount thereof exceeds 1.0 part by weight, an excessive amount of the coating agent may be adsorbed on the surface of the conductive metal powder, resulting in a problem in that electrical conductivity of a produced electrode may be deteriorated.

The use of the conductive metal powder coated with the coating agent enables the silicone oil included in the conductive paste to be positioned on the surface of the metal powder, thus completely preventing phase separation in the vehicle. That is, the coating with the coating agent makes it possible to control the degree of movement of the silicone oil to the surface of the conductive metal powder. By preventing phase separation due to incompatibility of the silicone oil with organic vehicles (organic solvents and organic binders, etc.), it is possible to secure storage stability of the provided conductive paste, and secure excellent slip properties to provide an effect of realizing ultra-fine line widths.

<Glass Frit>

A glass frit used is not limited. A leaded glass frit as well as a lead-free glass frit may be used. The composition, particle diameter, and shape of the glass frit are not particularly limited. Preferably, the glass frit includes, in terms of oxides, 5 to 29 mol % of PbO, 20 to 34 mol % of TeO₂, 3 to 20 mol % of Bi₂O₃, equal to or less than 20 mol % of SiO₂, and equal to or less than 10 mol % of B₂O₃, and includes an alkali metal (Li, Na, K, and the like) and an alkaline earth metal (Ca, Mg, and the like) in an amount of 10 to 20 mol %. By organically combining the amount of each component, it is possible to prevent an increase in line width of an electrode, ensuring excellent contact resistance at high sheet resistance, and ensuring excellent short-circuit current characteristics.

In particular, when the amount of PbO is too high, there is a problem in that it may be difficult to ensure eco-friendliness, and viscosity may become too low during melting and thus the line width of the electrode may increase during firing. Therefore, PbO is preferably included within the above range in the glass frit.

Meanwhile, the average particle diameter of the glass frit is not limited, but may fall within the range of 0.5 to 10 μm, and the glass frit may be used by mixing different types of particles having different average particle diameters. Preferably, at least one type of glass frit has an average particle diameter (D50) of equal to or greater than 2 μm and equal to or less than 10 μm. This makes it possible to ensure excellent reactivity during firing, and in particular, minimize damage to an n-layer at a high temperature, improve adhesion, and ensure excellent open-circuit voltage (Voc). It is also possible to reduce an increase in the line width of the electrode during firing. Further, the glass transition temperature (Tg) of the glass frit having an average particle diameter of equal to or greater than 2 μm and equal to or less than 10 μm is preferably less than 300° C. Since particles having a relatively large particle size are used, a problem such as uneven melting during firing may be prevented by lowering the glass transition temperature.

The amount of the glass frit is preferably 1 to 15% by weight with respect to the total weight of the conductive paste composition. When the amount thereof is less than 1% by weight, there is a possibility that electrical resistivity may increase due to incomplete firing. On the other hand, when the amount thereof is greater than 15% by weight, there is a possibility that electrical resistivity may increase due to too many glass components in a fired body of the glass powder.

<Organic Vehicle>

An organic vehicle is not limited, but may include an organic binder, a solvent, and the like. The use of the solvent may be omitted in some cases. The organic vehicle is not limited, but is preferably included in an amount of 1 to 10% by weight with respect to the total weight of the paste composition for the electrode.

The organic binder used in the paste composition for the electrode may include, but not limited to, a cellulose ester compound such as cellulose acetate, cellulose acetate butyrate, and the like; a cellulose ether compound such as ethyl cellulose, methyl cellulose, hydroxypropyl cellulose, hydroxyethyl cellulose, hydroxypropyl methyl cellulose, hydroxyethyl methyl cellulose, and the like; an acrylic compound such as polyacrylamide, polymethacrylate, polymethyl methacrylate, polyethyl methacrylate, and the like; and a vinyl compound such as polyvinyl butyral, polyvinyl acetate, polyvinyl alcohol, and the like. At least one of the binders may be selected and used.

As a solvent used for dilution of the composition, at least one of compounds selected from the group consisting of alpha-terpineol, texanol, dioctyl phthalate, dibutyl phthalate, cyclohexane, hexane, toluene, benzyl alcohol, dioxane, diethylene glycol, ethylene glycol monobutyl ether, ethylene glycol monobutyl ether acetate, diethylene glycol mono butyl ether, diethylene glycol mono butyl ether acetate, and the like is preferably used.

<Silicone Oil>

A silicone oil may be included in the conductive paste to maximize slip properties. The type of the silicone oil is not limited, but may include at least one selected from the group consisting of phenyl trimethicone, dimethicone, cyclomethicone, polydimethylsiloxane, and silicone gum. Also, a modified silicone oil may be used. Preferably, polysiloxane such as polydimethylsiloxane is used, and an unmodified polysiloxane oil is used in consideration of slip properties.

The silicone oil is included in an amount of 0.1 to 2% by weight with respect to the total weight of the conductive paste composition. When the amount of the silicone oil is less than 0.1% by weight, there is a problem in that the effect of improving the slip properties may be negligible. On the other hand, the amount thereof exceeds 2% by weight, there is a problem in that phase separation may occur even with the use of the coated metal powder and the additive. More preferably, the amount of the additive is 0.5 to 1.5% by weight.

<Additive>

An additive includes at least one selected from the group consisting of octyldodecyl neopentanoate, tridecyl neopentanoate, dioctyl adipate, isotearyl neopentanoate, and iodopropynyl butylcarbamate. Preferred is octyldodecyl neopentanoate. The use of the additive enables the silicone oil to be positioned on the surface of the coated conductive metal powder, thereby very effectively preventing phase separation with the organic vehicle.

The additive is included in an amount of 0.5 to 3% by weight with respect to the total weight of the conductive paste composition. When the amount of the additive is less than 0.5% by weight, there is a problem in that compatibility of the silicone oil may be poor, and thus phase separation may occur when preparing the conductive paste. On the other hand, when the amount thereof exceeds 3% by weight, there is a problem in composition design. Preferably, the amount of the additive is 0.5 to 1.5% by weight.

In addition, the conductive paste composition according to the present disclosure may further include, as needed, an additive generally known, for example, a dispersant, plasticizer, a viscosity modifier, a surfactant, an oxidizing agent, a metal oxide, a metal organic compound, and the like.

The above-described conductive paste composition for the solar cell electrode may be prepared in such a manner that the metal powder, glass frit, organic binder, solvent, and additive are mixed and dispersed, followed by filtering and degassing.

The present disclosure also provides a method of forming a solar cell electrode, characterized in that the conductive paste is coated on a substrate, dried, and fired, and provides a solar cell electrode manufactured by the method. In the method of forming the solar cell electrode according to the present disclosure, except for the use of the conductive paste including the coated metal powder, the substrate, printing, drying, and firing can be implemented by using methods generally used in manufacturing of solar cells.

In an example, the substrate may be a silicon wafer, the electrode produced from the paste according to the present disclosure may be a finger electrode or a busbar electrode of the front electrode, the printing may be screen printing or offset printing, the drying may be performed at to 350° C., and the firing may be performed at 600 to 950° C. Preferably, the firing is performed at 800 to 950° C., more preferably, high temperature/high speed firing is performed at 850 to 900° C. for 5 seconds to 1 minute, and the printing is performed to a thickness of 20 to 60 μm. Specific examples include the structure of a solar cell and a method of manufacturing the same disclosed in Korean Patent Application Publication Nos. 10-2006-0108550 and 10-2006-0127813, and Japanese Patent Application Publication Nos. 2001-202822 and 2003-133567.

The conductive paste according to the present disclosure is excellent in storage stability because phase separation is prevented, and when used in forming an electrode, its excellent slip properties makes it possible to alleviate the phenomenon of line width spreading during electrode formation. As a result, it is possible to stably implement an electrode having a fine line width, as well as improving the electrical characteristics of the electrode due to an increase in short-circuit current (Isc) due to the fine line width and the effect of reduced linear resistance, thereby improving power generation efficiency of solar cells.

Further, the conductive paste according to the present disclosure is applicable to a structure such as crystalline solar cell (P-type, N-type), passivated emitter solar cell (PESC), passivated emitter and rear cell (PERC), and passivated emitter rear locally diffused (PERL) cell, and also to modified printing processes such as double printing, dual printing, and the like.

### Example and Comparative Example

### (1) Example

After dispersing 100 g of a silver powder in 400 mL of pure water, 2.7 g of an octadecylamine ethanol solution (11.25 wt % octadecylamine amount) was added to a solution in which the silver powder was dispersed, followed by stirring at 4000 rpm for 20 minutes to subject the silver powder to surface treatment. Then, the stirring was stopped, the resulting mixture was filtered using a centrifuge, and a filter medium was washed with pure water, and dried at 70° C. for 12 hours to obtain a silver powder subjected to a primary surface treatment. This silver powder was subjected to grinding in a food mixer and disintegration in a jet-mill.

After mixing 100 g of the silver powder subjected to the surface treatment with 400 ml of alcohol, 2 g of a silicone oil (PMX-200 from Dow Corning) was added, followed by stirring for 10 minutes, and removing the alcohol. Thereafter, a binder, an additive, a dispersant, a leveling agent, a glass frit, and the like were added and dispersed using a three-roll mill, mixed with the silver powder subjected to a secondary surface treatment with the silicone oil, and then dispersed using the three-roll mill. Finally, degassing under reduced pressure was performed to prepare a conductive paste. Components and amounts of the prepared conductive paste are illustrated in Table 1 below.

TABLE 1

| Classification | Amount (wt %) |
|---|---|
| EC | 0.5 |
| EFKA-4330 | 0.5 |
| BYK180 | 0.7 |
| Texanol | 1.5 |
| Butyl cellosolve | 1.5 |
| Thixatrol ST | 0.3 |
| Dimethyl adipate | 1.5 |
| Octyldodecyl | 1 |
| neopentanoate | |
| Silicone oil | 1 |
| Silver powder | 89.5 |
| (ODA coating) | |
| Glass frit | 2 |

(1) Comparative Example After mixing 100 g of a silver powder with 400 ml of alcohol, 2 g of a silicone oil was added, followed by stirring for 10 minutes, and removing the alcohol. Thereafter, a binder, a dispersant, a leveling agent, a glass frit, and the like were added and dispersed using a three-roll mill, mixed with the silver powder subjected to surface treatment with the silicone oil, and then dispersed using the three-roll mill. Finally, degassing under reduced pressure was performed to prepare a conductive paste. Components and amounts of the prepared conductive paste are illustrated in Table 2 below.

TABLE 2

| Classification | Amount (wt %) |
|---|---|
| EC | 0.5 |
| EFKA-4330 | 0.5 |
| BYK180 | 0.7 |
| Texanol | 2 |
| Butyl cellosolve | 2 |
| Thixatrol ST | 0.3 |
| Dimethyl adipate | 1.5 |
| Silicone oil | 1 |
| Silver powder | 89.5 |
| Glass frit | 2 |

### Experimental Example (1) Evaluation of Solubility of Silicone Oil in Additive

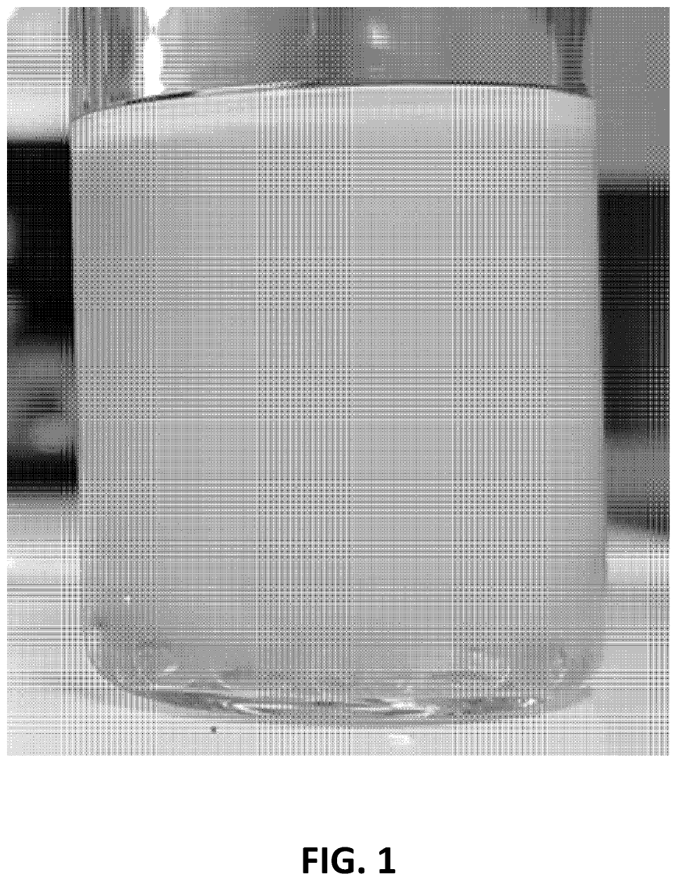

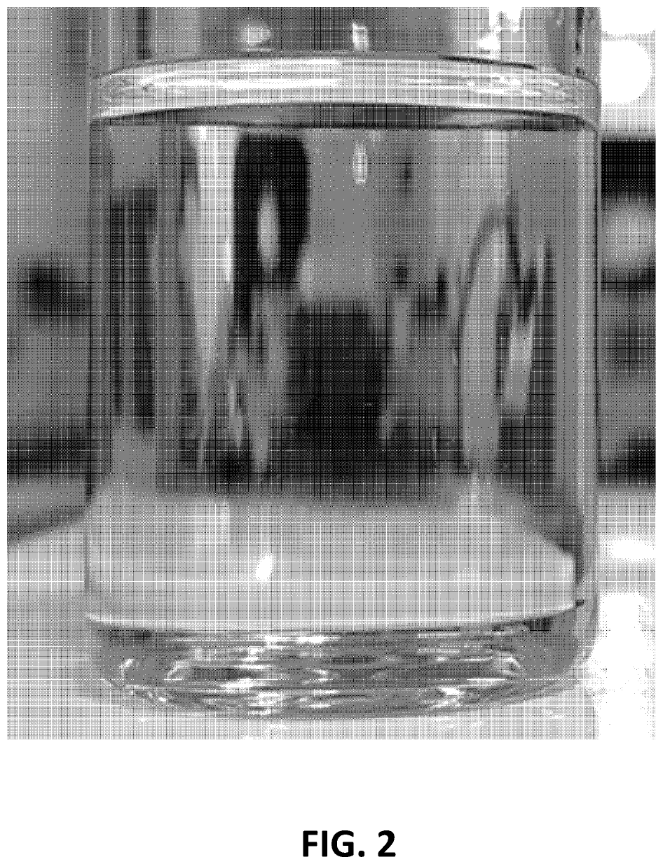

After adding a silicone oil to each additive, solubility of the silicone oil was compared and evaluated. Comparative evaluation of the solubility was conducted by visually observing transparency of a solution in which the silicone oil and the additive were mixed. FIG. 1 illustrates a solution in which butyl ether acetate (DBA) and a silicone oil are mixed in diethylene glycol, which is mainly used as a conventional solvent, and FIG. 2 illustrates a solution in which octyldodecyl neopentanoate and a silicone oil are mixed. As illustrated in FIG. 1, the solution obtained by mixing the DBA and the silicone oil is opaque, whereas, as illustrated in FIG. 2, the solution obtained by mixing the octyldodecyl neopentanoate and the silicone oil is transparent. It can be inferred from this that the solubility of the additives according to the present disclosure is high in the silicone oil.

### (2) Evaluation of Centrifugation Phase Separation

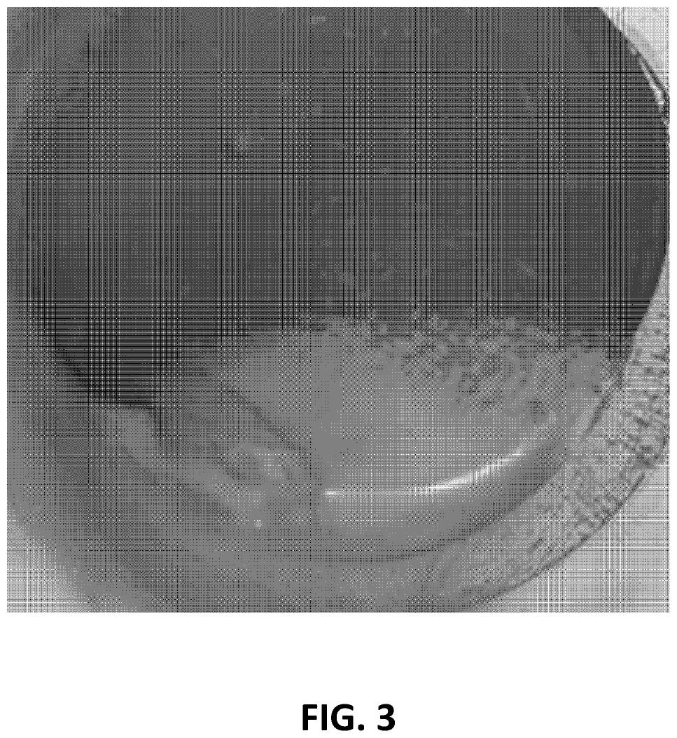

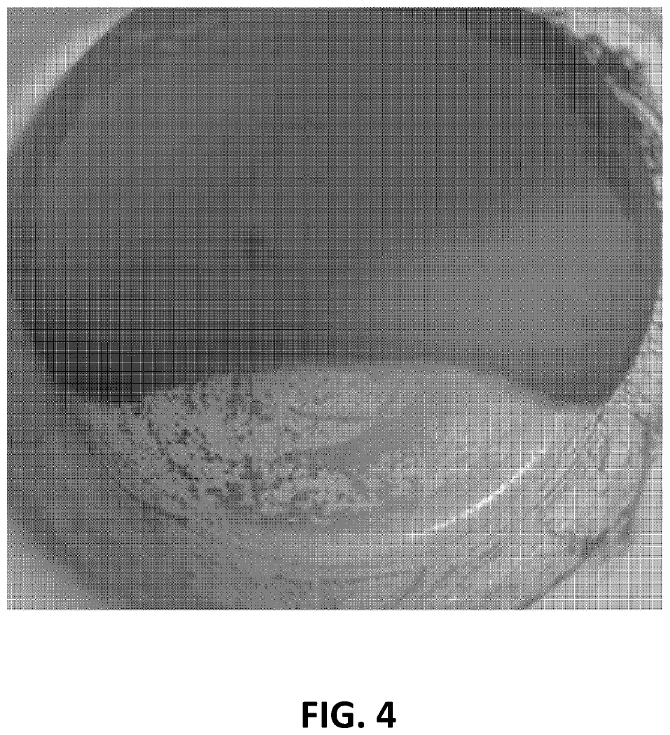

Evaluation was made whether the pastes prepared according to the above Example and Comparative Example were undergone phase separation during centrifugation under the same conditions. Images taken after centrifugation are illustrated in FIGS. 3 and 4. It can be seen from FIG. 3 that a liquid flow exists in a lower portion of the paste prepared according to Comparative example after centrifugation, whereas it can be seen from FIG. 4 that liquid separation does not occur in a lower portion of the paste prepared according to Example after centrifugation.

### (3) Measurement of Storage Modulus

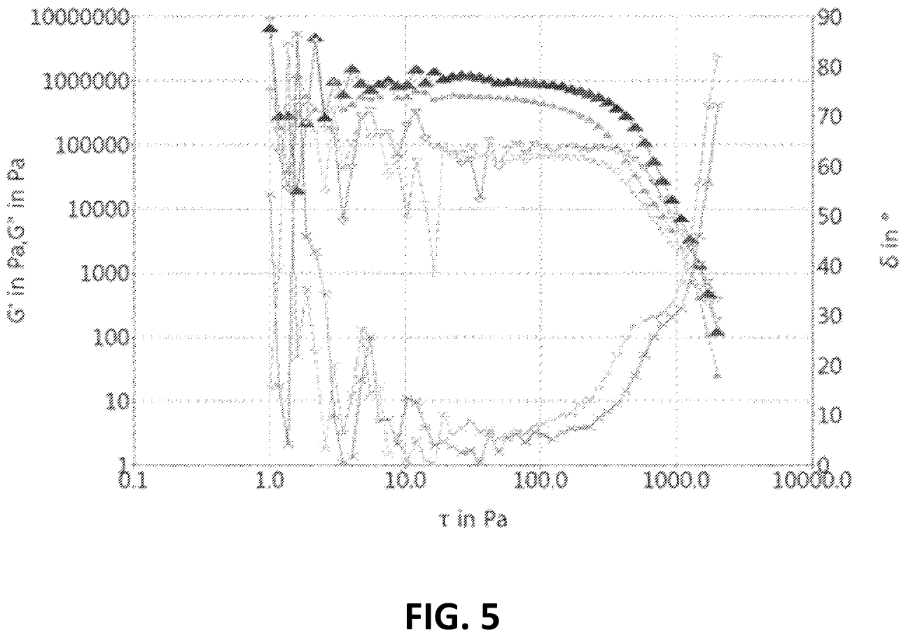

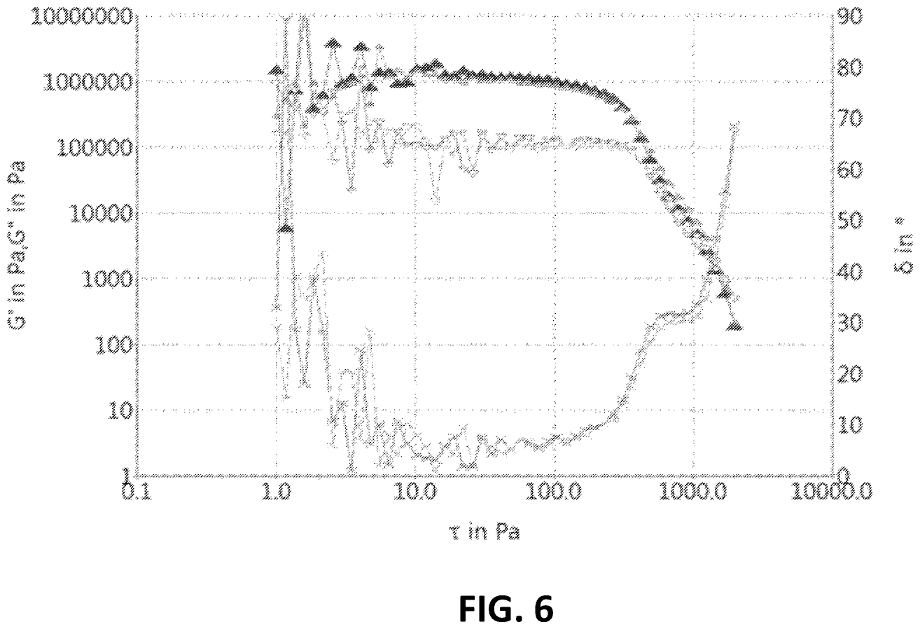

The prepared conductive pastes were measured for elastic modulus G′, viscosity modulus G″, and dissipation factor tan δ (G″/G′) through amplitude sweep at 25° C. using a rotational rheometer, HAAKE RheoStress1, and the results are illustrated in FIGS. 5 and 6. The results measured at the beginning are indicated by red data points, and those measured after 72 hours are indicated by yellow-green data points. It can be seen from FIG. 5 that the conductive paste prepared according to Comparative Example decreases in both the elastic modulus G′ and the viscosity modulus G″ over time, and in particular, considerably decreases in the elastic modulus, whereas it can be seen from FIG. 6 that the conductive paste prepared according to Example is stable without change over time.

1. A conductive paste for a solar cell electrode, the conductive paste comprising
a metal powder,
a glass frit,
an organic vehicle,
a silicone oil, and
an additive,
wherein the metal powder is coated with a coating agent including an alkyl amine-based compound having an amine group in an alkyl chain having 8 to 20 carbon atoms or an alkyl carboxy-based compound having a carboxyl group in an alkyl chain having 8 to 20 carbon atoms.

2. The conductive paste of claim 1, wherein the alkyl amine-based compound comprises at least one selected from the group consisting of triethylamine, heptylamine, octadecylamine, hexadecylamine, decylamine, octylamine, didecylamine, and trioctylamine.

3. The conductive paste of claim 1, wherein the alkyl carboxy-based compound comprises at least one selected from the group consisting of capric acid, lauric acid, myristic acid, palmitic acid, stearic acid, arachidic acid, myristoleic acid, palmitoleic acid, oleic acid, and linoleic acid.

4. The conductive paste of claim 1, wherein the silicone oil is included in an amount of 0.1 to 2% by weight with respect to the total weight of the conductive paste.

5. The conductive paste of claim 1, wherein the silicone oil comprises at least one selected from the group consisting of phenyl trimethicone, dimethicone, cyclomethicone, polydimethylsiloxane, and silicone gum.

6. The conductive paste of claim 1, wherein the additive is included in an amount of 0.5 to 3% by weight with respect to the total weight of the conductive paste.

7. The conductive paste of claim 1, wherein the additive comprises at least one selected from the group consisting of octyldodecyl neopentanoate, tridecyl neopentanoate, dioctyl adipate, isotearyl neopentanoate, and iodopropynyl butylcarbamate.

8. A solar cell comprising:
a front electrode provided on a substrate; and
a back electrode provided under the substrate,
wherein the front electrode is produced by applying the conductive paste of claim 1, and then drying and firing the conductive paste.
